(19) United States
(12) Patent Application Publication
(10) Pub. No.: US 2025/0169370 A1
(43) Pub. Date: May 22, 2025

(54) APPARATUS AND METHOD OF IMPLEMENTING A PROBABILISTIC BIT (P-BIT) CIRCUIT WITH ENHANCED TUNABILITY

(71) Applicant: KING FAHD UNIVERSITY OF PETROLEUM AND MINERALS, Dhahran (SA)

(72) Inventors: Saleh Ahmad S BUNAIYAN, Dhahran (SA); Feras Mohamad Ameer AL-DIRINI, Dhahran (SA)

(73) Assignee: KING FAHD UNIVERSITY OF PETROLEUM AND MINERALS, Dhahran (SA)

(21) Appl. No.: 18/417,631

(22) Filed: Jan. 19, 2024

Related U.S. Application Data
(60) Provisional application No. 63/599,735, filed on Nov. 16, 2023.

(51) Int. Cl. H10N 50/10; G11C 11/16; H10B 61/00; H10N 50/80

(52) U.S. Cl. CPC H10N 50/10; G11C 11/161; G11C 11/1673; H10B 61/20; H10N 50/80

(57) ABSTRACT

An apparatus and method for implementing a probabilistic bit (p-bit) circuit with enhanced tunability is disclosed. The apparatus includes multiple magnetic tunnel junctions (MTJs) connected in series to a drain of a transistor. The apparatus also includes a resistor connected to a source of the transistor. The resistor is of a resistance value that is selected based on an average equivalent resistance value of a series combination of the multiple MTJs. The apparatus includes a comparator configured to receive voltage from the drain (“drain voltage”) and generate an output voltage based on a reference voltage and the drain voltage. The method includes generating, using a first circuitry, a drain voltage that is fluctuating over time, and generating, using a second circuitry, an output voltage that is varying continuously over time by comparing the fluctuating voltage with a reference voltage.

### CROSS-REFERENCE TO RELATED APPLICATION

The present application claims benefit of priority to U.S. Provisional Application No. 63/599,735 having a filing date of Nov. 16, 2023, which is incorporated herein by reference in its entirety.

### STATEMENT OF PRIOR DISCLOSURE BY AN INVENTOR

Aspects of the present disclosed were disclosed in “MTJ-Based p-Bit Designs for Enhanced Tunability” presented at 2022 IEEE Nanotechnology Materials and Devices Conference (NMDC) which is incorporated herein by reference in its entirety.

### STATEMENT OF ACKNOWLEDGEMENT

The inventors acknowledge the financial support provided by the Interdisciplinary Research Center (IRC) for Advanced Materials, King Fahd University of Petroleum & Minerals (KFUPM), Riyadh, Saudi Arabia through Project No. INAM2306.

### BACKGROUND

### Technical Field

The present disclosure is directed to probabilistic computing circuits. More particularly the present disclosure relates to an apparatus and a method of implementing a probabilistic bit circuit with enhanced tunability.

### Description of Related Art

The “background” description provided herein is for the purpose of generally presenting the context of the disclosure. Work of the presently named inventors, to the extent it is described in this background section, as well as aspects of the description which may not otherwise qualify as prior art at the time of filing, are neither expressly or impliedly admitted as prior art against the present invention.

Devices with stochastic temporal dynamics are building blocks of probabilistic computing systems. A promising candidate for such systems is the probabilistic bit (p-bit), which exhibits its stochasticity through a stochastic magnetic tunnel junction (MTJ), emulating the behavior of random number generators (RNGs) with the unique feature of tunable random response. In contrast to CMOS-based RNGS, these devices can achieve aperiodic stochasticity with a much lower number of transistors. Where thousands of transistors are used for CMOS RNGs, MTJ-based RNGS can be implemented with a few transistors and a single MTJ and can have much lower energy consumption. Typically, MTJs are viewed as deterministic devices, however lowering the energy barrier of their free magnet layer (as shown in FIG. 1A), defined in the literate as a low barrier magnet (LBM), gives rise to a stochastic device that oscillates between two resistance states; parallel (R_{P}) and anti-parallel (R_{AP}). Incorporating such a stochastic MTJ in a p-bit circuit (as shown in FIG. 2A), gives rise to a bit that produces a fluctuating output voltage between high and low states according to a tunable probability that is controlled by the input voltage of the p-bit. Reported implementations of p-bits, demonstrate the ability of tuning the output probability as a function of the input voltage, however the reported input voltage range within which these p-bits exhibit stochastic behavior is very small (on the order of sub 0.5 V), which may limit the scalability of p-bit networks.

Moreover, bipolar MTJs have only two possible resistance states corresponding to digital ‘0’ and digital ‘1’ respectively, enabling their mainstream use in memory applications. When made stochastic, such MTJs will fluctuate between these two possible states only. The conventional p-bit implementation is an NMOS transistor with a stochastic MTJ connected in series, with its output at the drain side in a 1T1M structure, as shown in FIG. 2A. A p-bit based on a bipolar MTJ (using either perpendicular or in-plane magnetic anisotropy (PMA/IMA) magnets) has limited tunability within the stochastic range, as the MTJ will stochastically fluctuate between the two possible resistance states only, restricting the p-bit response to a staircase function as shown in FIG. 2B. It can be seen that the stochastic range is small for such an implementation, and this is mainly because the drain voltage has quadratic dependance on the input voltage (V_{Drain}∝I_{Drain} and I_{Drain}∝V²_{IN}). Adding a source resistance adjusts the V_{Drain} dependency to become a linear function of V_{IN}. However, the resistance will only slightly widen the input voltage range within which the p-bit has a stochastic response, without addressing the staircase behavior, that originates from the binary behavior of the MTJ.

Accordingly, it is one of the objects of the present disclosure to provide apparatus and methods for improving the tunability of p-bits based on bipolar MTJs.

### SUMMARY

In an exemplary embodiment, an apparatus for implementing a probabilistic bit (p-bit) circuit with enhanced tunability is described. The apparatus includes multiple magnetic tunnel junctions (MTJs) connected in series. The apparatus also includes a resistor connected to a source of the transistor. The resistor is of a resistance value that is selected based on an average equivalent resistance value of a series combination of the multiple MTJs. The apparatus also includes a comparator configured to receive voltage from the drain (“drain voltage”) and generate an output voltage based on a reference voltage and the drain voltage.

In another exemplary embodiment, apparatus for implementing a probabilistic bit (p-bit) circuit with enhanced tunability is described. The apparatus includes multiple continuous magnetic tunnel junctions (MTJs) connected in series to a drain of a transistor. The apparatus also includes a comparator configured to receive a first voltage from the drain at an inverting terminal as a drain voltage, receive an input voltage at a non-inverting terminal, and generate an output voltage based on the input voltage and the drain voltage.

In another exemplary embodiment, a method of implementing a probabilistic bit (p-bit) circuit with enhanced tunability is described. The method includes generating, using a first circuitry, a drain voltage that is fluctuating over time. The method also includes generating, using a second circuitry, an output voltage that is varying continuously over time by comparing the fluctuating voltage with a reference voltage.

The foregoing general description of the illustrative embodiments and the following detailed description thereof are merely exemplary aspects of the teachings of this disclosure and are not restrictive.

### BRIEF DESCRIPTION OF THE DRAWINGS

A more complete appreciation of this disclosure and many of the attendant advantages thereof will be readily obtained as the same becomes better understood by reference to the following detailed description when considered in connection with the accompanying drawings, wherein:

FIG. 1A depicts an energy distribution curve for magnetic tunnel junctions (MTJs), according to an exemplary scenario.

FIG. 1B depicts a flow diagram of a MATLAB simulation of stochastic MTJ resistance, according to an exemplary scenario.

FIG. 2A depicts a conventional a one transistor one MTJ (1T1M) probabilistic bit (p-bit) implementation with V_{DD} of 5 V (volts), according to an exemplary scenario.

FIG. 2B depicts a p-bit response (time-averaged Vₒᵤₜ vs V_{IN}) without a source resistance for a single bipolar MTJ with integrated tunneling magnetoresistance (TMR) of 70% and G0-1 of 9 kΩ, according to an exemplary scenario.

FIG. 3A depicts an apparatus of the present technology with two bipolar MTJs, according to certain other embodiments.

FIG. 3B depicts apparatus of the present technology with three bipolar MTJs, according to certain other embodiments.

FIG. 4A-FIG. 4D depict results for a p-bit with N identical bipolar MTJs, according to certain other embodiments.

FIG. 5A-FIG. 5C depict results for a p-bit with non-identical bipolar MTJs, according to certain other embodiments.

FIG. 6A-FIG. 6C depict results for a p-bit with a continuous MTJ, according to certain other embodiments.

FIG. 7A depicts another apparatus for implementing a probabilistic bit (p-bit) circuit with enhanced tunability, according to certain embodiments.

FIG. 7B depicts a p-bit response of the apparatus with continuous MTJ, according to certain embodiments.

FIG. 8A-FIG. 8B depict results for a p-bit with a continuous MTJ, according to certain embodiments.

FIG. 9 is an exemplary flowchart of a method of implementing a p-bit circuit with enhanced tunability, according to certain embodiments.

### DETAILED DESCRIPTION

In the drawings like reference numerals designate identical or corresponding parts throughout the several views. Further, as used herein, the words “a,” “an” and the like generally carry a meaning of “one or more,” unless stated otherwise.

Furthermore, the terms “approximately,” “approximate,” “about,” and similar terms generally refer to ranges that include the identified value within a margin of 20%, 10%, or preferably 5%, and any values therebetween.

Bipolar magnetic tunnel junctions (MTJs) have only two possible resistance states corresponding to digital ‘0’ and digital ‘1’ respectively, enabling their mainstream use in memory applications. When made stochastic, such MTJs will fluctuate between these two possible states only. Additionally, MTJs are viewed as deterministic devices, however lowering the energy barrier of their free magnet layer, defined in the literate as a low barrier magnet (LBM), gives rise to a stochastic device that oscillates between two resistance states; parallel (R_{P}) and anti-parallel (R_{AP}). Incorporating such a stochastic MTJ in a probabilistic bit (p-bit) circuit gives rise to a bit that produces a fluctuating output voltage between high and low states according to a tunable probability that is controlled by the input voltage of the p-bit. Several reported implementations of p-bits demonstrated the ability of tuning the output probability as a function of the input voltage, however the reported input voltage range within which these p-bits exhibit stochastic behavior is very small (on the order of sub 0.5 volts (V)), which may limit the scalability of p-bit networks.

The present technology is directed towards relaxing the needed accuracy in tuning the p-bit output and enabling applications that require critical controllable tunability of the output probability. The present technology improves tunability range of previously reported p-bit designs and presents a number of modified MTJ-based p-bit designs that enable enhanced tunability over an extended probabilistic range of the p-bit. Aspects of this disclosure are directed to an apparatus and method of implementing a probabilistic bit (p-bit) circuit with enhanced tunability. The present technology provides modified MTJ-based p-bit designs that enable enhanced tunability over an extended probabilistic range of the p-bit.

In several embodiments, in order to extend the stochastic range of the p-bit, a design modification is proposed, where V_{Gate} is fixed and V_{IN} is applied to the voltage reference of the comparator (V_{REF}). This way the gate voltage can be chosen to allow the maximum fluctuation range at the drain side, while the input applied to the comparator reference (new V_{IN}) will scan the whole range of the voltage supply (−V_{dd} to V_{dd}). As discussed before, when there is no resistance at the source terminal, the drain voltage would be more sensitive to the gate voltage. Hence, removing the source resistance would also further increase the fluctuation range at the drain, giving rise to a more continuous p-bit response. Moreover, continuous MTJs can achieve adequate tunability of the p-bit with a single MTJ, while bipolar MTJs need multiple series-MTJs to approach the response of continuous MTJs. Accordingly, when it comes to fabrication, continuous MTJs would be more attractive than bipolar ones as they require less area. Nonetheless, the first experimental implementation of p-bit networks using stochastic MTJs employed almost binary MTJs. On the other hand, nanosecond speeds were reported recently in easy-plane MTJs, which appear to be closer to continuous MTJs rather than binary. Accordingly, no consensus can be claimed about which stochastic MTJ type is expected to dominate in commercial applications. The present technology provides new p-bit designs that are modified versions of the conventional p-bit implementation. The apparatus of the present technology improves the stochastic range, enhancing it by up to an order of magnitude in comparison to previously reported designs. Consequently, this enhanced stochastic range would facilitate enhanced scalability of p-bit networks.

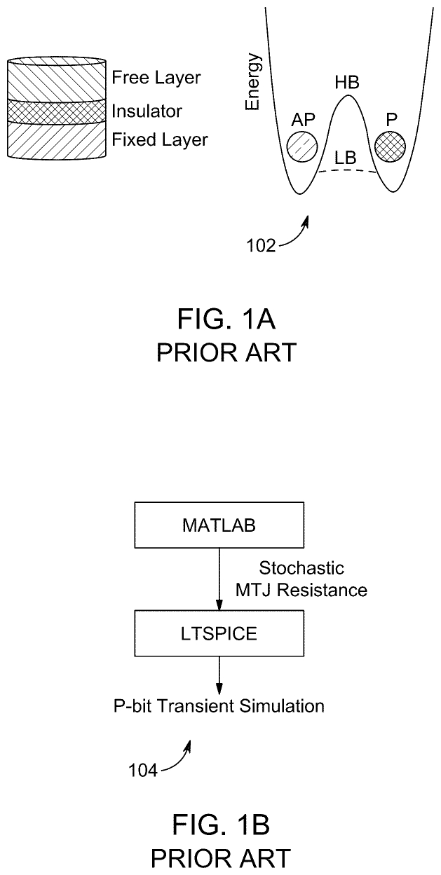

FIG. 1A depicts an energy distribution curve 102 for MTJs, according to an exemplary scenario. Typically, MTJs are viewed as deterministic devices, however lowering the energy barrier of their free magnet layer (FIG. 1A), defined in the literate as a low barrier magnet (LBM), gives rise to a stochastic device that oscillates between two resistance states; parallel (R_{P}) and anti-parallel (R_{AP}). The left side of the energy curve represents the anti-parallel (AP) state while the right side represents the parallel (P) state. The energy curve illustrates that at high barrier more energy is needed to move from AP to P or vice versa, while for low barrier much less energy is needed (e.g., thermal noise).

FIG. 1B depicts a flow diagram 104 of MATLAB simulation of stochastic MTJ resistance, according to an exemplary scenario. Aiming to relax the needed accuracy in tuning the p-bit output and enabling applications that require critical controllable tunability of the output probability, this paper studies the tunability range of previously reported p-bit designs and presents a number of modified MTJ-based p-bit designs that enable enhanced tunability over an extended probabilistic range of the p-bit. All presented designs are verified through SPICE simulations. MATLAB is used to generate an emulation of the stochastic MTJ resistance fluctuations and this in turn is fed into LTSPICE (LTspice is a SPICE-based analog electronic circuit simulator computer software, provided by semiconductor manufacturer Analog Devices), which is used for simulating the p-bit behavior, as illustrated by FIG. 1B. First, p-bit designs based on bipolar MTJs are studied and then designs based on continuous MTJs are investigated.

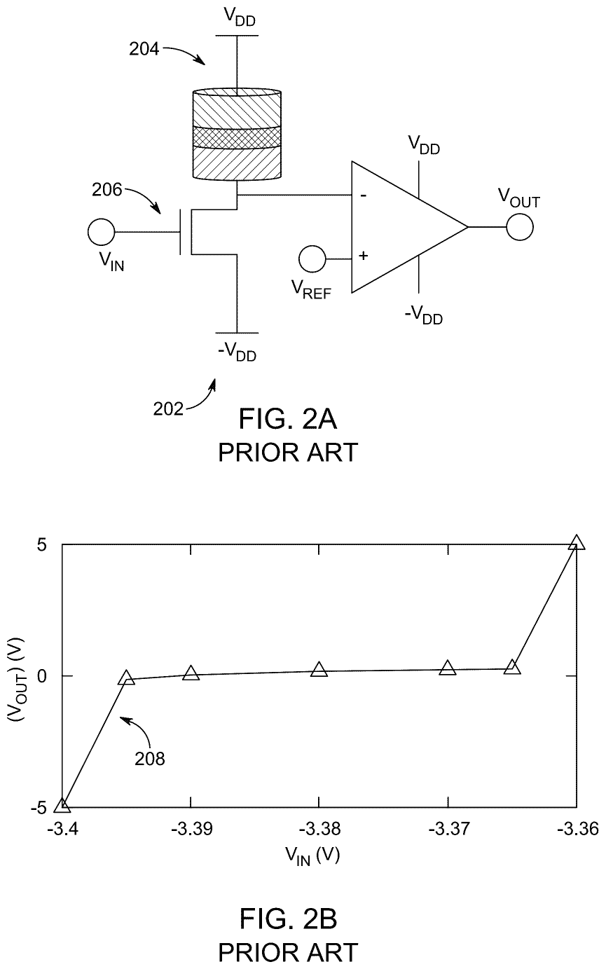

FIG. 2A depicts a conventional one transistor one MTJ (1T1M) p-bit implementation 202 with V_{DD} of 5 V (volts), in accordance with an exemplary scenario. The conventional 1T1M p-bit implementation 202 includes a stochastic MTJ 204 in a p-bit circuit, as shown in FIG. 2A, that gives rise to a bit that produces a fluctuating output voltage between high and low states according to a tunable probability that is controlled by the input voltage of the p-bit. Reported implementations of p-bits demonstrated the ability of tuning the output probability as a function of the input voltage, however the reported input voltage range within which the p-bits exhibit stochastic behavior is very small (on the order of sub 0.5 V), which may limit the scalability of p-bit networks. The conventional p-bit implementation 202 includes a NMOS transistor 206 with a stochastic MTJ 204 connected in series, with its output at the drain side in the 1T1M structure, as shown in FIG. 2A.

FIG. 2B depicts a p-bit response (time-averaged Vₒᵤₜ vs V_{IN}) 208 without a source resistance for a single bipolar MTJ with integrated tunneling magnetoresistance (TMR) of 70% and G0-1 of 9 kilo ohms (kΩ), according to an exemplary scenario. A p-bit based on a bipolar MTJ (using either perpendicular or in-plane magnetic anisotropy (PMA/IMA) magnets has limited tunability within the stochastic range, as the MTJ will stochastically fluctuate between the two possible resistance states only, restricting the p-bit response 208 to a staircase function as shown in FIG. 2B. It can be seen that the stochastic range is small for such an implementation, and this is mainly because the drain voltage has quadratic dependence on the input voltage (V_{Drain} & I_{Drain} and I_{Drain} & V²_{IN}).

Adding a source resistance adjusts the V_{Drain} dependency to become a linear function of V_{IN}. However, the resistance will only slightly widen the input voltage range within which the p-bit has a stochastic response, without addressing the staircase behavior, which originates from the binary behavior of the MTJ. For subsequent simulations, a source resistance is added between the source terminal of the transistor and −V_{DD} and is chosen as Rₛ˜R_{MTJ_Min}, while any variation in the current passing across the MTJ is assumed to not affect the MTJ state.

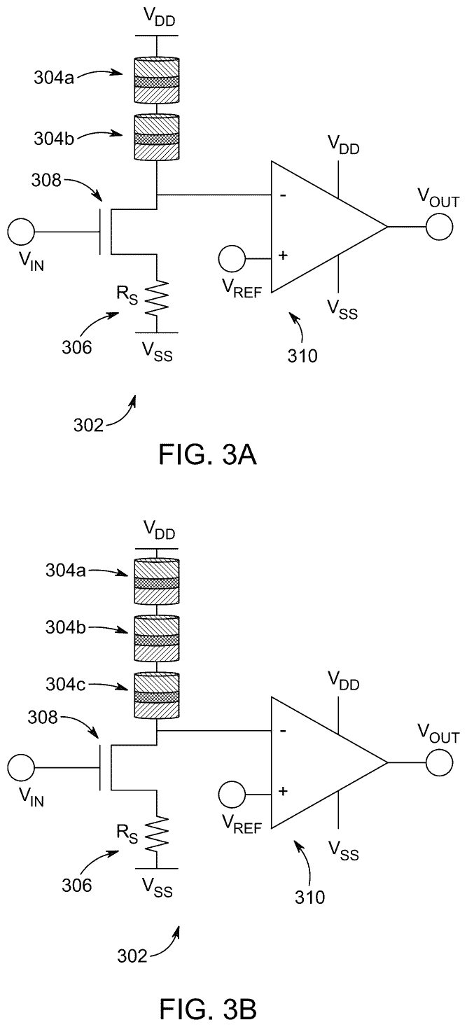

FIG. 3A depicts an apparatus 302 of the present technology with two bipolar MTJs, according to certain other embodiments. The apparatus 302 includes a magnetic tunnel junction (MTJs) 304a-b connected to a drain of a transistor 308, a resistor 306 connected to a source of the transistor 308. The resistor 306 is of a resistance value that is selected based on an average equivalent resistance value of a series combination of the multiple MTJs connected to the source. A comparator 310 is configured to receive voltage from the drain (“drain voltage”) and generate an output voltage based on a reference voltage and the drain voltage. The MTJs 304a-b are bipolar MTJs whose resistance value fluctuates to any one of two resistance states.

In an implementation, the bipolar MTJs 304a-b are identical MTJs, where the resistance states of the identical MTJs 304a-b are spaced uniformly, and a number of resistance states is equal to N+1 where N is the number of MTJs.

In an implementation, the bipolar MTJs 304a-b are non-identical MTJs, the resistance states of the non-identical MTJs 304a-b are spaced non-uniformly, and wherein a number of resistance states are equal to 2N where N is the number of MTJs.

In an implementation, the MTJs 304a-b are continuous MTJs whose resistance value fluctuates to any value between two resistance states.

In an implementation, a variable input voltage (V_{IN}) is provided to a gate of the transistor 308, and a fixed reference voltage (V_{REF}) is input to the comparator 310. As the input voltage (V_{IN}) varies, the drain voltage varies, and as the drain voltage varies the output voltage (V_{OUT}) of the p-bit also varies. Thus, as the input voltage varies, the output voltage also varies. In some embodiments, the drain voltage is input to an inverting-terminal of the comparator 310 and the reference voltage is applied to a non-inverting terminal of the comparator 310.

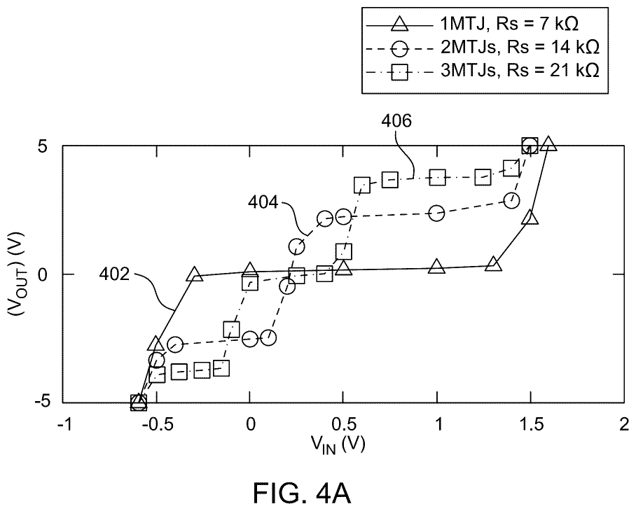

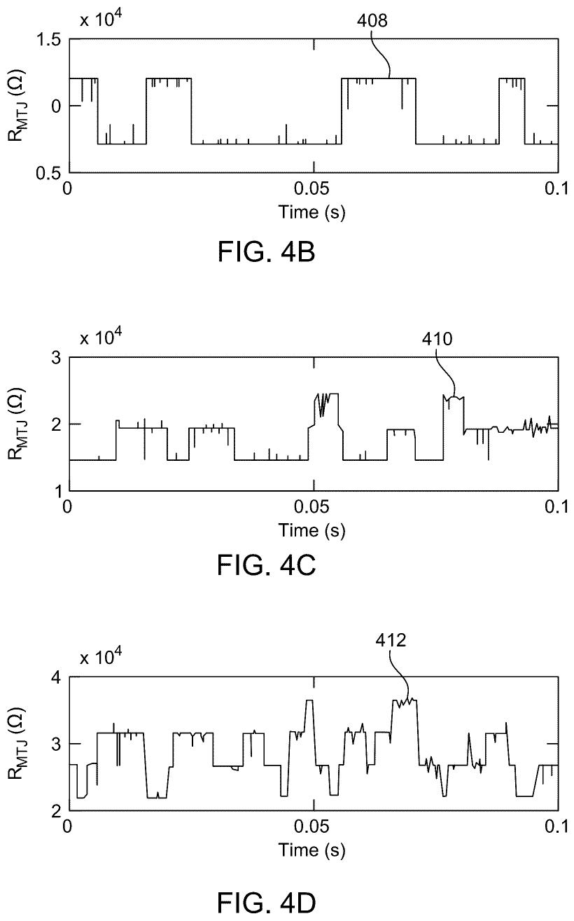

FIG. 3B depicts the apparatus of the present technology with three bipolar MTJs 304a-c, according to certain other embodiments. In an implementation, adding multiple (N) bipolar MTJs in series, such as bipolar MTJs 304a-c shown in FIG. 3B, may smoothen the p-bit response towards becoming more continuous, and as the number of series MTJs is increased the response becomes more continuous, thereby improving the tunability of p-bits. This 1TNM structure can be implemented either by identical MTJs or non-identical MTJs. Since the equivalent MTJ resistance is based on the summation of all series MTJ resistances, different resistance combinations can result in the same summation (replicated states), hence for identical MTJs 304a-c the total number of possible resistance states as a function of the number of series MTJs will be N+1 (as shown in FIG. 4A)

FIG. 4A-FIG. 4D depict results for a p-bit with N identical bipolar MTJs, according to certain other embodiments. FIG. 4A depicts p-bit responses 402, 404 and 406 for multiple identical MTJs, where a first response curve 402 corresponding to 1 MTJ and Rₛ of 7 kilo ohms, a second response curve 404 corresponding to 2 MTJs and Rₛ of 14 kilo ohms, and a third response curve 406 corresponding to 3 MTJs and Rₛ of 21 kilo ohms. The value of Rₛ is increased with increasing N in order to match the average equivalent resistance of the series combination of the N MTJs. FIGS. 4B-4D depict MTJ equivalent resistances 408, 410 and 412 corresponding to 1 MTJ, 2 MTJs and 3 MTJs in series, respectively, with TMR of 70% and G₀⁻¹ of 9 kΩ. The use of identical MTJs ensures that all resistance states are spaced uniformly. The simulation indicates that increasing the number of identical MTJs will adjust the p-bit to become more tunable (continuous) by increasing the number of levels of the staircase response of the p-bit, as shown in FIG. 4A. On the other hand, using non-identical MTJs will significantly increase the total number of possible resistance combinations to become 2N, with states being non-uniformly spaced. Accordingly, non-identical MTJs are expected to have a more tunable yet still staircase shape than identical ones. However, it is worth mentioning that if two resistance states are near each other, they may converge to represent a single state, and hence, the total the number of states may be less than 2N.

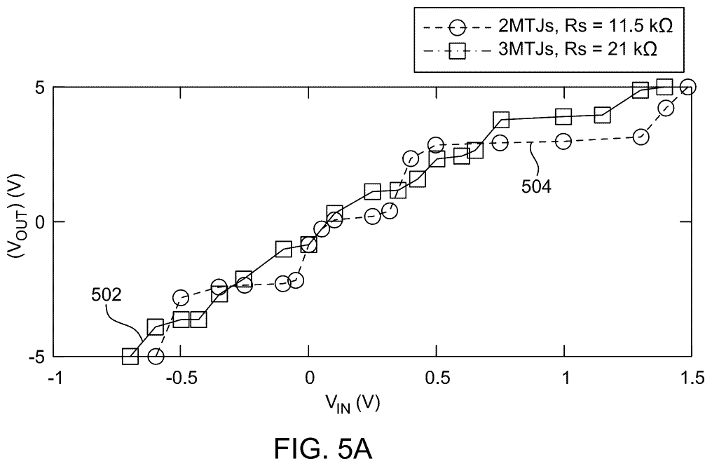

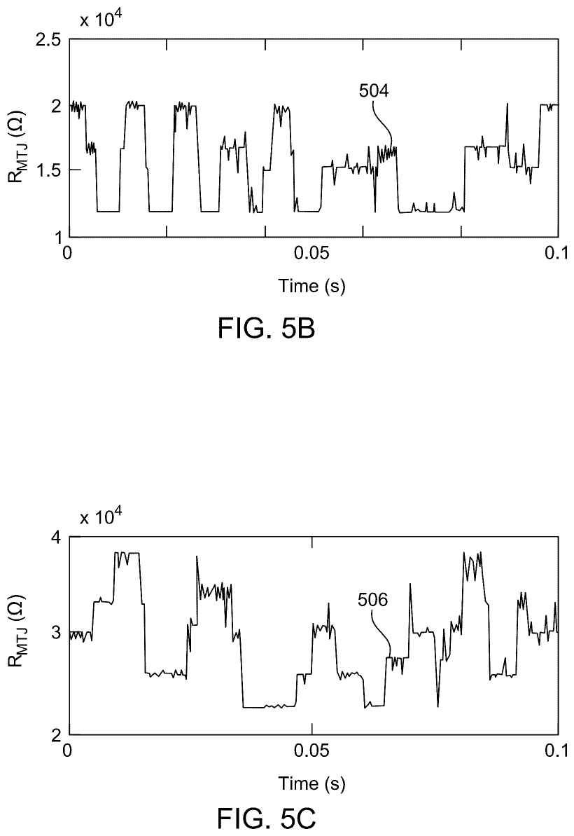

FIG. 5A-FIG. 5C depicts results for a p-bit with non-identical bipolar MTJs, according to certain other embodiments. FIG. 5A depicts a p-bit response for multiple non-identical MTJs, including a first response curve 502 corresponding to two MTJs and Rₛ being 11.5 kilo ohms, and a second response curve 504 corresponding to three MTJs and Rₛ being 21 kilo ohms. The value of Rₛ is increased with increasing N in order to match the average equivalent resistance of the series combination of the N non-identical MTJs. FIGS. 5B-5C depict an MTJ equivalent resistances 504 and 506 for two, and three MTJs in series, respectively, with TMR=70%, G₀₁⁻¹=9 kΩ, G₀₂⁻¹=6 kΩ, and G₀₃⁻¹=13.5 kΩ respectively. It can be observed that compared to identical MTJs (shown in FIG. 4A), non-identical ones (shown in FIG. 5A) result in a more continuous and a more tunable response of the p-bit. It can be inferred from the result of non-identical MTJs (shown in FIG. 5A) that increasing the number of possible resistance states of the MTJ would gradually smoothen the staircase response.

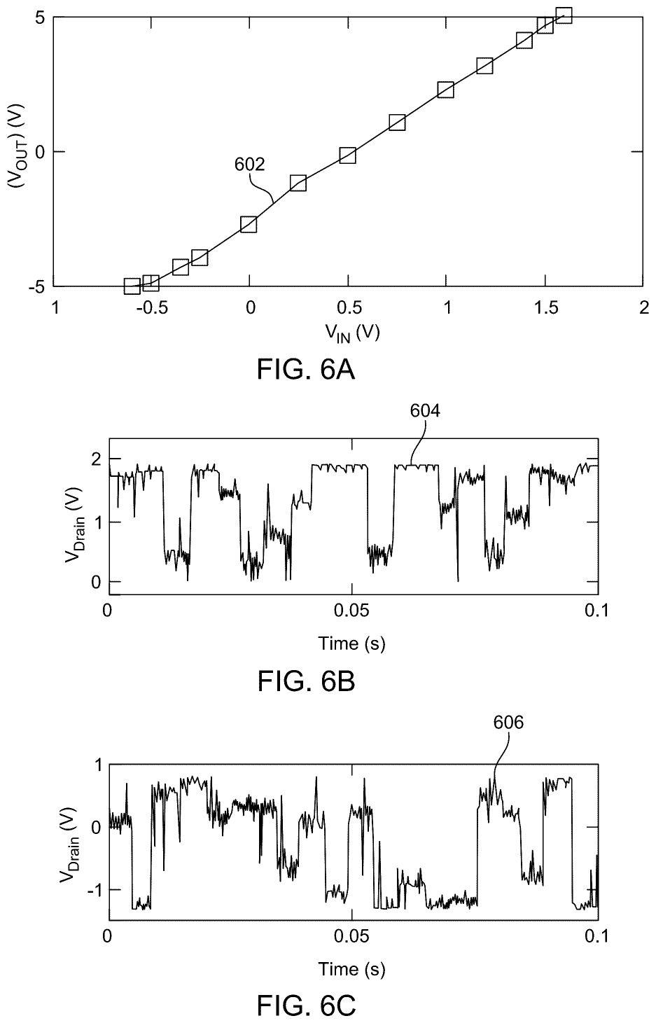

FIG. 6A-FIG. 6C depicts results for a p-bit with a continuous MTJ, according to certain other embodiments. In several implementations of the apparatus 302 of the present technology, continuous MTJs are used that include analog resistance states (e.g., using circular or isotropic magnets) that fluctuate at any value between the parallel (R_{P}) and the anti-parallel (R_{AP}) state. The fact that the MTJ resistance is analog makes the stochastic range of a p-bit employing a continuous stochastic MTJ much more tunable than one employing a bipolar MTJ, as indicated by the simulation 602 in FIG. 6A, where it is clear that continuous MTJs do not exhibit any staircase response. FIG. 6A depicts a p-bit response 602 when fixing V_{REF} and varying V_{IN}, and with a source resistance Rₛ=7 kΩ. FIG. 6B-FIG. 6C depicts voltage (V_{Drain}) versus time curves 604 and 606, with transient V_{Drain} at V_{IN} at −0.5 V and 0.75 V respectively and TMR at 70% and G₀⁻¹ at 9 kilo ohms (kΩ).

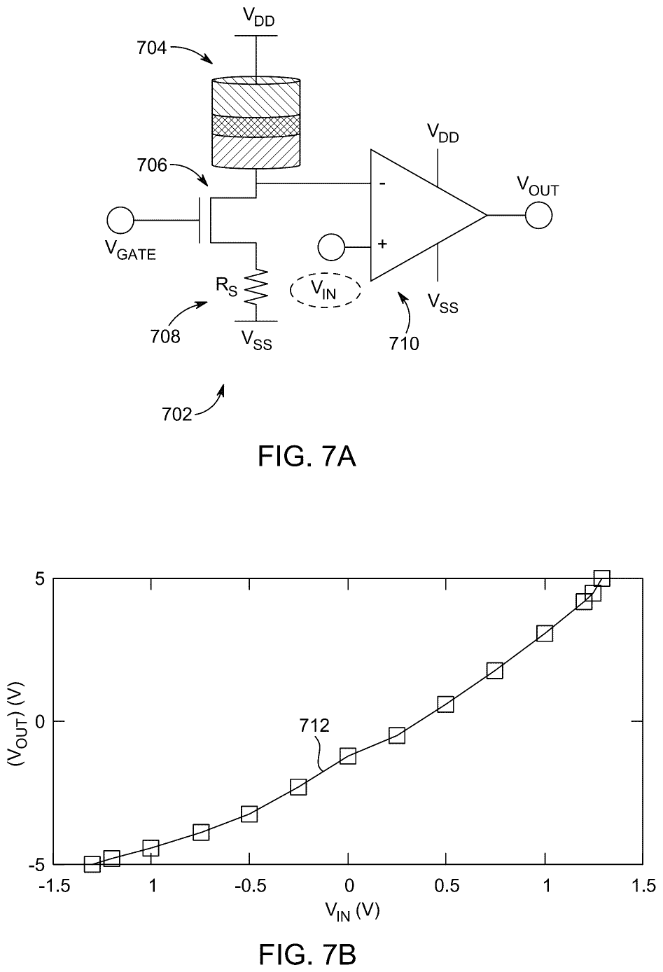

FIG. 7A depicts another apparatus 702 for implementing a probabilistic bit (p-bit) circuit with enhanced tunability, according to certain other embodiments. In the apparatus 702, the voltage input to the gate (V_{Gate}) is fixed to a particular value and the input voltage (V_{IN}) is applied to the voltage reference of a comparator 710 (V_{REF}). The output voltage (V_{OUT}) varies as the input voltage provided to the comparator 710 varies. The apparatus 702 includes an MTJ 704 connected to a drain of a transistor 706, a resistor 708 connected to a source of the transistor 706, where the resistor 708 is of a resistance value that is selected based on an average equivalent resistance value of a series combination of the multiple MTJs, and a comparator 710 configured to receive voltage from the drain (“drain voltage”) and generate an output voltage based on the input voltage (new V_{IN}) and the drain voltage. The apparatus 702 expands the stochastic range of the p-bit, where V_{Gate} is fixed and V_{IN} is applied to the voltage reference of the comparator 710 (V_{REF}). This way the gate voltage can be chosen to allow the maximum fluctuation range at the drain side, while the input applied to the comparator reference (V_{IN}) will scan the whole range of the voltage supply (−V_{dd} to V_{dd}). Simulation results for the apparatus 702, shown in FIG. 7B, demonstrate that the stochastic range would indeed increase, with a more continuous response of the p-bit and no staircase response.

FIG. 7B depicts a p-bit response 712 of the apparatus 702 of FIG. 7A, according to certain embodiments. FIG. 7B depicts the p-bit response 712 with Rₛ=7 kΩ, TMR=70%, G₀⁻¹=9 kΩ and V_{DD}=−V_{SS}=5 V. FIG. 7A-FIG. 7B demonstrate that the stochastic range would indeed increase, with a more continuous response of the p-bit and no staircase response.

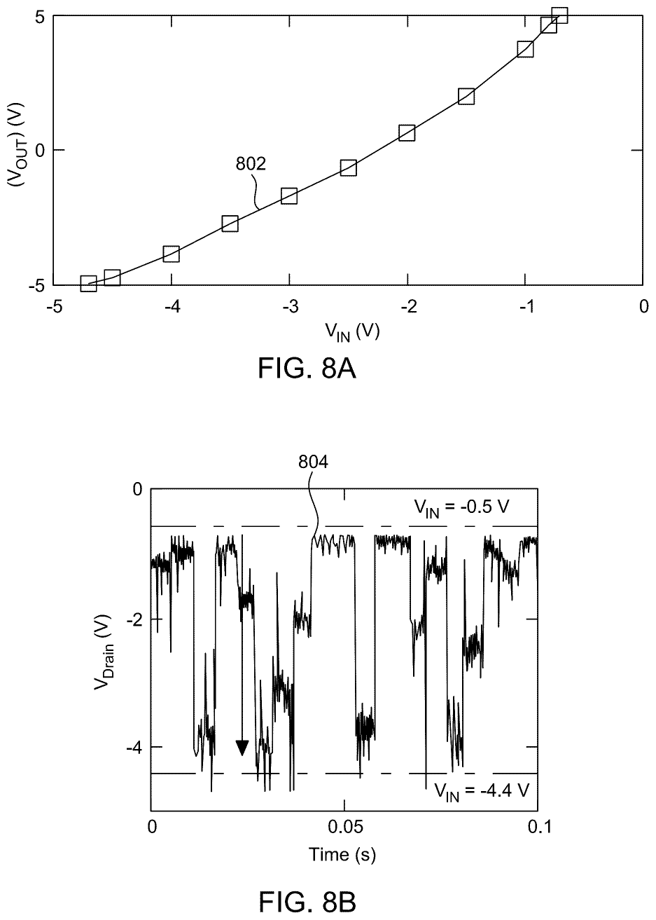

In an implementation, the resistance value of the resistor 708 is configured to be “0”, that is, the resistor 708 may be removed from the circuit, which results in the p-bit response being more smooth or continuous, as described at least with reference to FIGS. 8A and 8B below.

FIG. 8A-FIG. 8B depicts results for a p-bit with a continuous MTJ, according to certain embodiments. More particularly, FIG. 8A depicts a p-bit response 802 when fixing V_{Gate} and applying the V_{IN}, without a source resistance, and FIG. 8B depicts a curve 804 obtained by plotting V_{Drain} in volts (along Y-axis) versus time in seconds (along X-axis), where the transient V_{Drain} as V_{IN} scans the whole range of values for V_{Drain}, with TMR=70% and G0-1=9 kΩ. When there is no resistance at the source terminal, the drain voltage is more sensitive to the gate voltage. Hence, removing the source resistance would also further increase the fluctuation range at the drain, giving rise to the p-bit response 802 shown in FIG. 8A, with the gate voltage fixed at −3.35 V. Once again, the stochastic range is further extended, this time almost double the two previous cases (˜4 V). Compared to other designs, this design may need more control over the gate voltage due to the high drain dependency. Accordingly, continuous MTJs can achieve adequate tunability of the p-bit with a single MTJ, while bipolar MTJs need multiple series-MTJs to approach the response of continuous MTJs. Accordingly, when it comes to fabrication, continuous MTJs may be more attractive than bipolar ones as they require less area. Nonetheless, the first experimental implementation of p-bit networks using stochastic MTJs employed almost binary MTJs. On the other hand, nanosecond speeds may be obtained in easy-plane MTJs, which appear to be closer to continuous MTJs rather than binary.

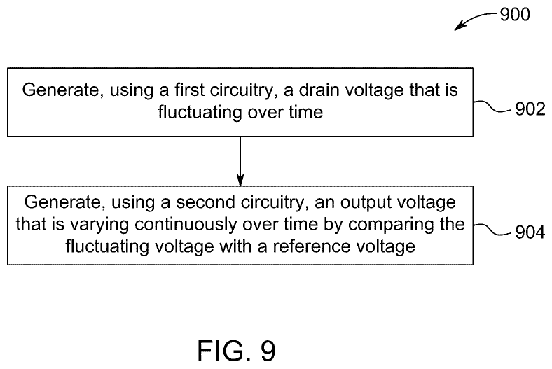

FIG. 9 is an exemplary flowchart 900 of a method of implementing a probabilistic bit (p-bit) circuit with enhanced tunability, according to certain embodiments. In a brief overview of the implementation of the flowchart 900, at step 902, a drain voltage that is fluctuating over time is generated using a first circuitry. At step 904, an output voltage that is varying continuously over time is generated by comparing the fluctuating voltage with a reference voltage, the output voltage is generated by using a second circuitry.

In an implementation, generating the fluctuating voltage includes inputting a first voltage to a gate of a transistor of the first circuitry as a gate voltage and generating the drain voltage using multiple MTJs connected in series to a drain of the transistor.

In an implementation, generating the output voltage includes inputting the drain voltage to an inverting terminal of a comparator of the second circuitry, and inputting the reference voltage to a non-inverting terminal of the comparator.

In an implementation, the output voltage varies as the gate voltage is varied, and wherein the reference voltage is fixed at a particular value.

In an implementation, the output voltage varies as the reference voltage is varied and the gate voltage is fixed at a particular value to provide maximum fluctuation range for the drain voltage, as described at least with reference to FIG. 7A.

The present technology provides MTJ-based p-bit designs that enable enhanced tunability over an extended probabilistic range of the p-bit. Moreover, continuous MTJs can achieve adequate tunability of the p-bit with a single MTJ, while bipolar MTJs need multiple series-MTJs to approach the response of continuous MTJs. Accordingly, when it comes to fabrication, continuous MTJs would be more attractive than bipolar ones as they require less area. Nonetheless, the first experimental implementation of p-bit networks using stochastic MTJs employed almost binary MTJs. On the other hand, nanosecond speeds may be obtained in easy-plane MTJs, which appear to be closer to continuous MTJs rather than binary. Accordingly, no consensus can be claimed about which stochastic MTJ type is expected to dominate in commercial applications. The present technology provides new p-bit designs that are modified versions of the conventional p-bit implementation. The apparatus of the present technology improves the stochastic range, enhancing it by up to an order of magnitude in comparison to previously reported designs. Consequently, this enhanced stochastic range would facilitate enhanced scalability of p-bit networks.

The exemplary circuit elements described in the context of the present disclosure may be replaced with other elements and structured differently than the examples provided herein. Moreover, circuitry configured to perform features described herein may be implemented in multiple circuit units (e.g., chips), or the features may be combined in circuitry on a single chipset.

The above-described hardware description is a non-limiting example of corresponding structure for performing the functionality described herein.

Obviously, numerous modifications and variations of the present disclosure are possible in light of the above teachings. It is therefore to be understood that within the scope of the appended claims, the invention may be practiced otherwise than as specifically described herein.

1. An apparatus for implementing a probabilistic bit (p-bit) circuit with enhanced tunability, the apparatus comprising:
multiple magnetic tunnel junctions (MTJs) connected in series to a drain of a transistor;
a resistor connected to a source of the transistor, wherein the resistor is of a resistance value that is selected based on an average equivalent resistance value of a series combination of the multiple MTJs; and
a comparator configured to receive voltage from the drain (“drain voltage”) and generate an output voltage based on a reference voltage and the drain voltage.

2. The apparatus of claim 1, wherein the MTJs are bipolar MTJs whose resistance value fluctuates to any one of two resistance states.

3. The apparatus of claim 2, wherein the bipolar MTJs are identical MTJs, wherein resistance states of the identical MTJs are spaced uniformly, and wherein a number of resistance states is equal to N+1 where N is the number of MTJs.

4. The apparatus of claim 2, wherein the bipolar MTJs are non-identical MTJs, wherein resistance states of the non-identical MTJs are spaced non-uniformly, and wherein a number of resistance states is equal to 2^{N} where N is the number of MTJs.

5. The apparatus of claim 1, wherein the MTJs are continuous MTJs whose resistance value fluctuates to any value between two resistance states.

6. The apparatus of claim 1, wherein the drain voltage varies as an input voltage provided to a gate of the transistor varies.

7. The apparatus of claim 6, wherein the output voltage varies as the input voltage provided to the gate of the transistor varies.

8. The apparatus of claim 1, wherein the comparator is configured to receive an input voltage as the reference voltage, and wherein the output voltage varies as the input voltage provided to the comparator varies.

9. The apparatus of claim 8, wherein the drain voltage is determined based on a voltage provided to a gate of the transistor, and wherein the voltage input to the gate is fixed to a particular value.

10. The apparatus of claim 8, further comprising:
configuring the resistance value of the resistor to 0.

11. An apparatus for implementing a probabilistic bit (p-bit) circuit with enhanced tunability, the apparatus comprising:
multiple continuous magnetic tunnel junctions (MTJs) connected in series to a drain of a transistor; and
a comparator configured to:
receive a first voltage from the drain at an inverting terminal as a drain voltage,
receive an input voltage at a non-inverting terminal, and
generate an output voltage based on the input voltage and the drain voltage.

12. The apparatus of claim 11, wherein the output voltage varies as the input voltage provided to the comparator varies.

13. The apparatus of claim 12, wherein the drain voltage is determined based on a voltage input to a gate of the transistor, wherein the voltage input to the gate is fixed to a particular value.

14. The apparatus of claim 11, further comprising:
a resistor connected to a source of the transistor, wherein the resistor is of a resistance value that is selected based on an average equivalent resistance value of a series combination of the multiple MTJs.

15. The apparatus of claim 11, wherein the input voltage is fixed at a reference voltage, and wherein the output voltage varies as a voltage provided to a gate of the transistor varies.

16. A method of implementing a probabilistic bit (p-bit) circuit with enhanced tunability, the method comprising:
generating, using a first circuitry, a drain voltage that is fluctuating over time; and
generating, using a second circuitry, an output voltage that is varying continuously over time by comparing the fluctuating voltage with a reference voltage.

17. The method of claim 16, wherein generating the fluctuating voltage includes:
inputting a first voltage to a gate of a transistor of the first circuitry as a gate voltage; and
generating the drain voltage using multiple magnetic tunnel junctions (MTJs) connected in series to a drain of the transistor.

18. The method of claim 16, wherein generating the output voltage includes:
inputting the drain voltage to an inverting terminal of a comparator of the second circuitry, and
inputting the reference voltage to a non-inverting terminal of the comparator.

19. The method of claim 17, wherein the output voltage varies as the gate voltage is varied, and wherein the reference voltage is fixed at a particular value.

20. The method of claim 17, wherein the output voltage varies as the reference voltage is varied and the gate voltage is fixed at a particular value to provide maximum fluctuation range for the drain voltage.
